(19) United States
(12) Patent Application Publication
(10) Pub. No.: US 2025/0176118 A1
(43) Pub. Date: May 29, 2025

(54) CABINET FOR ELECTRICAL EQUIPMENT

(71) Applicant: DRHINO LIMITED, Doncaster (GB)

(72) Inventor: Anthony FULLER, Doncaster (GB)

(21) Appl. No.: 18/957,972

(22) Filed: Nov. 25, 2024

(30) Foreign Application Priority Data
Nov. 23, 2023 (GB) 2317899.9

(51) Int. Cl. H05K 5/02; H05K 5/00

(52) U.S. Cl. CPC H05K 5/0214; H05K 5/10

(57) ABSTRACT

A cabinet for electrical equipment is constructed by cutting high-pressure compact laminate to establish a plurality of walls and a roof. The high-pressure compact laminate has a core and a durable outer surface. The roof has a lower portion, an upper portion and support members. The support members are configured to support the upper portion upon the lower portion while defining an air gap between the lower portion and the upper portion. Vent holes are cut in the lower portion to facilitate the venting of warm air from inside the cabinet and the vent holes are covered with a mesh to prevent the ingress of solids and liquids.

### CROSS REFERENCE TO RELATED APPLICATIONS

This application claims priority from United Kingdom Patent Application number 2317899.9, filed on Nov. 23, 2023, the whole contents of which are incorporated herein by reference.

### TECHNICAL FIELD

The present invention relates to an apparatus for establishing a cabinet for electrical equipment. In particular, the present invention relates to a cabinet for electrical equipment having walls and a roof consisting of high-pressure compact laminate.

### BACKGROUND OF THE INVENTION

An electrical equipment cabinet with walls and a roof cut from a high-pressure compact laminate is disclosed in GB 2 576 932, assigned to the present applicant. A problem with cabinets of this type is that electrical equipment will often generate a degree of heat and difficulties may be encountered in terms of providing sufficient ventilation in order to remove this heat.

The integrity of the cabinet must be maintained while at the same time the ingress of solids and liquids must be prevented.

### BRIEF SUMMARY OF THE INVENTION

According to a first aspect of the present invention, there is provided an apparatus establishing a cabinet for electrical equipment, comprising a plurality of walls and a roof, wherein: said walls and said roof consist of high pressure compact laminate having a core and a durable outer surface; said roof comprises a lower portion, an upper portion and support members; said support members support said upper portion upon said lower portion while defining an air gap between said lower portion and said upper portion; said lower portion includes a plurality of vent holes to facilitate the venting of warm air from inside the cabinet; and said vent holes are covered by a mesh to prevent the ingress of solids and liquids.

In an embodiment, the roof is sloped and the pitch of the upper portion is substantially the same as the pitch of lower portion.

In an embodiment, the mesh is a stainless-steel mesh, the stainless-steel mesh is applied over an upper surface of the vent holes and the stainless-steel mesh is blistered upwards at the position of the vent holes.

In an embodiment, the roof is a coupled roof defining a ridge, such that the upper portion comprises a first board sloping in a first direction and a second board sloping in a second direction. The lower portion may include a third board and a fourth board and these may be identified as having a ridge section and a gutter section.

The ridge section of the third board may include a plurality of vent holes and the ridge section of the fourth board includes a plurality of vent holes. The gutter section of the third board may include first obstructors and second obstructors between support members; the gutter section of the fourth board may include first obstructors and second obstructors between support members; a lower surface of the first board may include third obstructors located between support members and between the first obstructors and the second obstructors of the third board; and a lower surface of the second board may include third obstructors located between support members and between the first obstructors and the second obstructors of the fourth board. The obstructors may take the form of brushes but in an embodiment the obstructors are solid baffles that allow air to flow over while preventing the ingress of solid objects. In an embodiment, the obstructors slope to facilitate the removal of condensed water.

According to a second aspect of the present invention, there is provided a method of constructing a cabinet for electrical equipment, comprising the steps of: cutting high pressure compact laminate to establish a plurality of walls and a roof, wherein said high pressure compact laminate has a core and a durable outer surface; arranging the roof upon the walls, wherein the roof has a lower portion, an upper portion and support members; configuring the support members to support the upper portion upon the lower portion while defining an air gap between the lower portion and the upper portion; cutting a plurality of vent holes in the lower portion to facilitate the venting of warm air from inside the cabinet; and covering the vent holes with a mesh to prevent the ingress of solids and liquids.

Embodiments of the invention will be described, by way of example only, with reference to the accompanying drawings. The detailed embodiments show the best mode known to the inventor and provide support for the invention as claimed. However, they are only exemplary and should not be used to interpret or limit the scope of the claims. Their purpose is to provide a teaching to those skilled in the art. Components and processes distinguished by ordinal phrases such as “first” and “second” do not necessarily define an order or ranking of any sort.

### BRIEF DESCRIPTION OF THE SEVERAL VIEWS OF THE DRAWINGS

FIG. 1 shows a cabinet for housing electrical equipment;

FIG. 2 illustrates a high-pressure compact laminate;

FIG. 3 shows a base panel of a cabinet;

FIG. 4 shows a wall for a cabinet;

FIG. 5 shows an orifice cut into a bevelled edge;

FIG. 6 shows portions of a connection device;

FIG. 7 shows use of a location tool;

FIG. 8 shows the first portion of the connector engaging with the second portion of the connector;

FIG. 9 illustrates the connection of walls;

FIG. 10 illustrates the creation of a gap between wall edges;

FIG. 11 shows a bevelled edge with additional connection devices

FIG. 12 shows the addition of a second wall;

FIG. 13 shows a first edge of a first wall being connected to a second edge of a second wall;

FIG. 14 shows the cabinet of FIG. 1 with an upper portion raised to show the lower portion;

FIG. 15 details a mesh deployed over vent holes; and

FIG. 16 details obstructors for preventing ingress.

### DETAILED DESCRIPTION OF EMBODIMENTS OF THE INVENTION

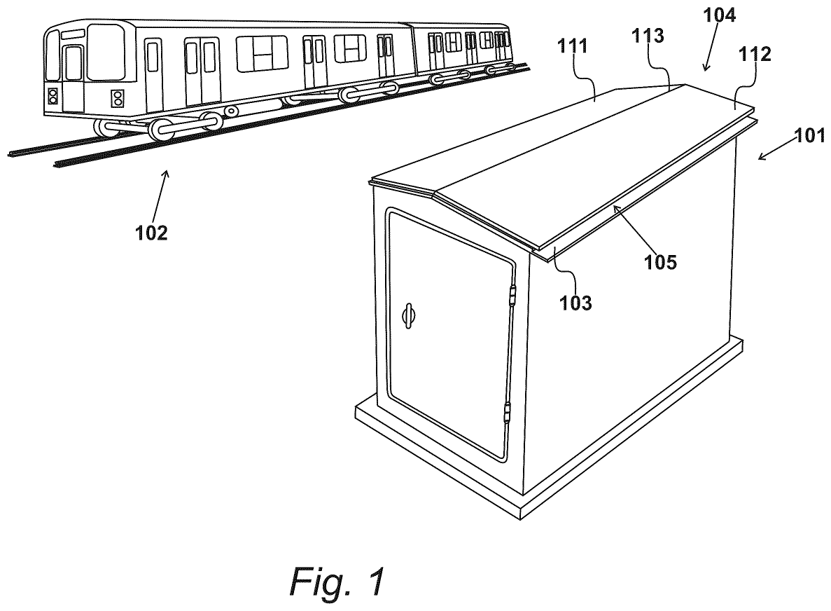

### FIG. 1

A cabinet 101 is shown in FIG. 1 for housing electrical equipment. In this example, the cabinet 101 is positioned close to a railway line 102 and includes electrical equipment relating to railway related systems. As such, the cabinet 101 is exposed to the environment and should therefore be constructed in a way that resists environmental degradation. Furthermore, the cabinet should also be resistant to vandalism, including the application of unauthorised spray-paint.

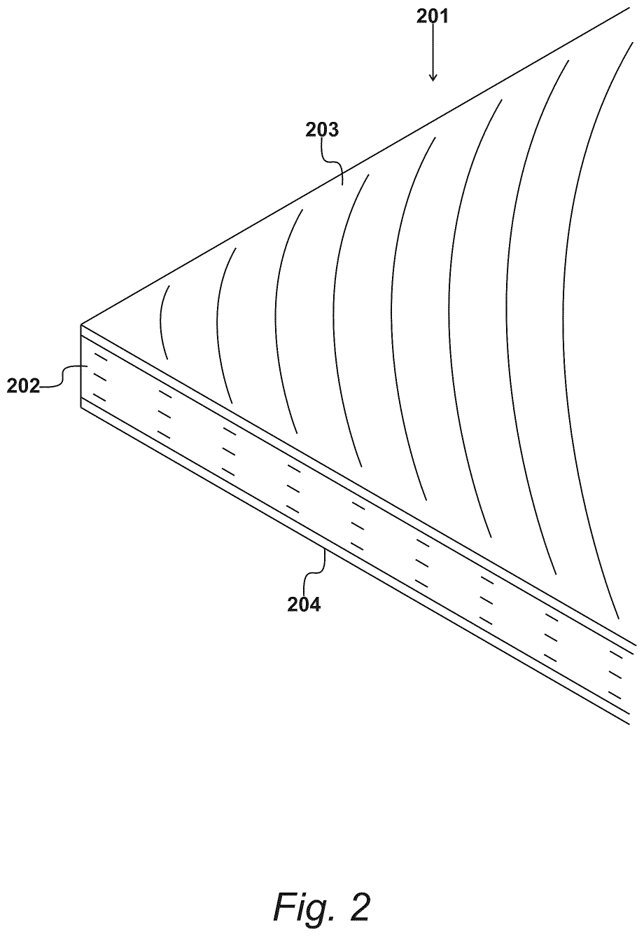

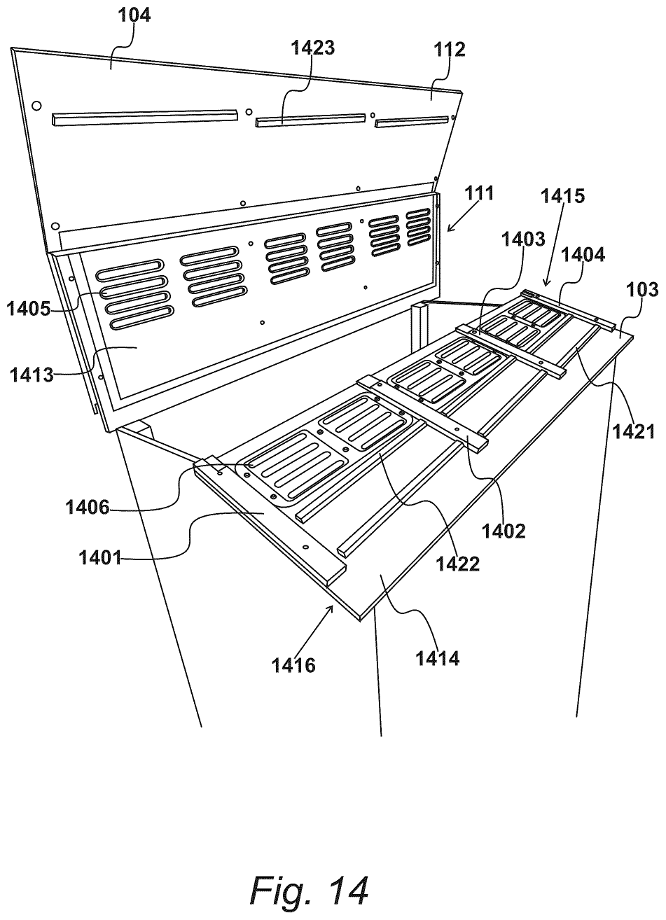

The cabinet 101 includes a plurality of walls and a roof. The walls and the roof consist of high-pressure compact laminates, of the type described with reference to FIG. 2. The roof comprises a lower portion 103 and an upper portion 104 which are separated by support members, described with reference to FIG. 14. The support members support the upper portion 104 upon the lower portion 103 while defining an air gap 105 between the lower portion 103 and the upper portion 104.

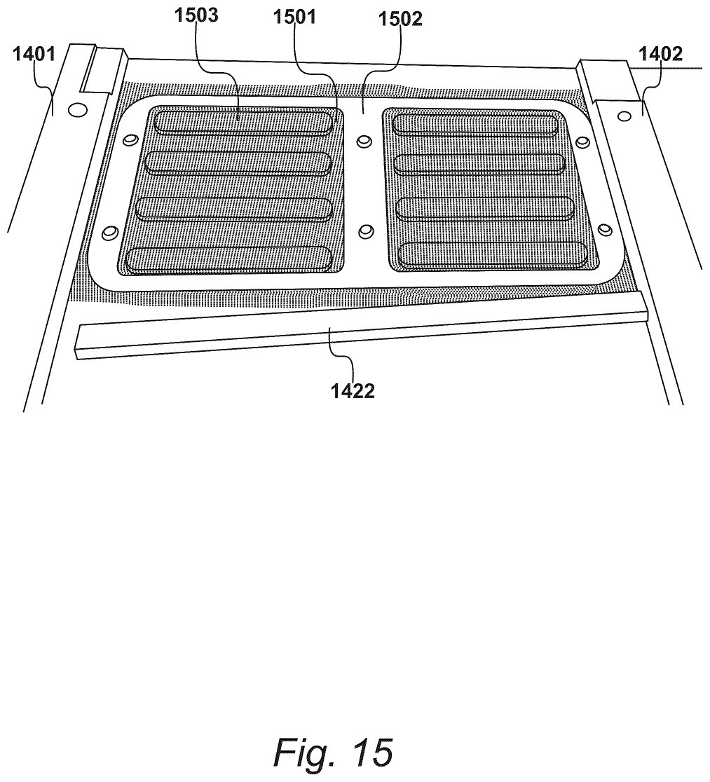

The lower portion includes a plurality of vent holes, described with reference to FIG. 15, to facilitate the venting of warm air from inside the cabinet. The vent holes are covered by a mesh to prevent the ingress of solids and liquids.

It would be possible for the roof 104 to be flat but when deployed outdoors, it is preferable for the roof to be sloped. In the embodiment shown in FIG. 1, the pitch of the upper portion 104 is substantially the same as the pitch of the lower portion 103.

In an alternative embodiment and as previously shown in GB 2 576 932, assigned to the present applicant, the roof could be a mono pitch roof sloping from one side of the cabinet to the other side of the cabinet. However, in the embodiment shown in FIG. 1, a couple roof is shown, such that the upper portion 104 comprises a first board 111 sloping in a first direction and a second board 112 sloping in a second direction, thus defining a ridge 113.

### FIG. 2

A high-pressure compact laminate 201 is shown in FIG. 2, which includes a core 202 and an outer surface 203. The outer surface includes a polyurethane acrylate binder. In an embodiment, a similar inner surface 204 is provided, that is also formed form a polyurethane acrylate binder.

Material of the type illustrated in FIG. 2 is available from commercial sources, such as Trespa International BV, of The Netherlands, under the commercial designation Trespa (registered trade mark) Meteon (registered trade mark). The material may be identified as a “panel”, on the basis that it is primarily constructed for application as exterior cladding. Typical examples have a thickness of eight millimetres and the material has an expected lifespan of fifty years.

Trespa Meteon is a low maintenance decorative construction panel consisting of seventy percent (by weight) of paper or residual wood from the industrial processing of softwoods and thirty percent by weight of a phenolic binder, making up the core 202. The binder is a completely hardened, consisting of an insoluble thermo-setting resin which, in this embodiment, is made of phenol/formalin.

In this formulation, the outer surface may be decorative and as such includes pigments in a solvent free polyurethane acrylate binder that is fully cured and hardened. This particular implementation does not use heavy metals, biocides, plasticises, inorganic fibres, halogens or any ozone depleting products or preservatives.

Thus, in an embodiment, the walls and roof are cut from panels of high-pressure compact laminate and as such present cut edges. The cut edges are protected by the application of a primer. Before the primer is applied, a grinding operation is performed upon the cut edges, followed by a cleansing operation.

In an embodiment, the cabinet provides a housing for electrical equipment and comprises a base, a plurality of walls, each having a durable outer surface and side edges and connection devices for connecting the plurality of walls at adjacent edges without penetrating the durable outer surfaces, and a roof.

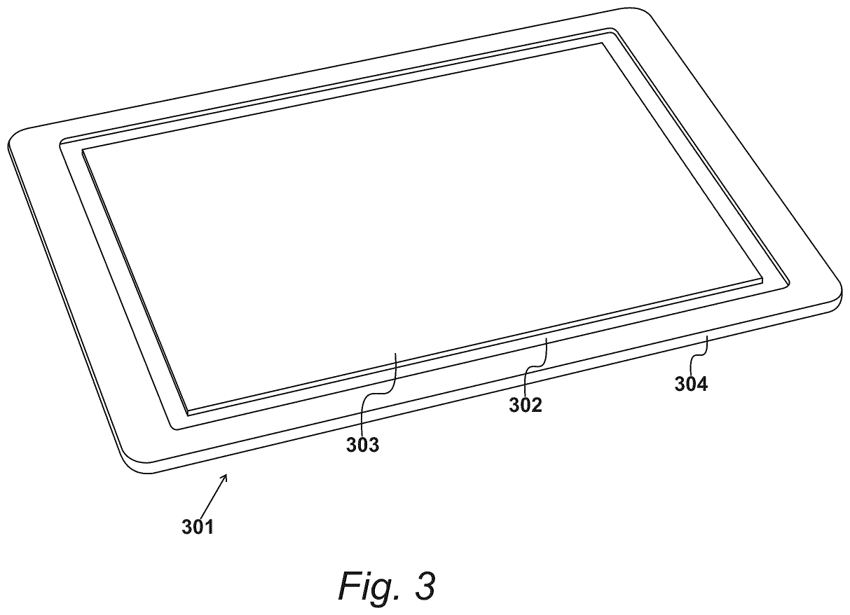

### FIG. 3

A base panel 301 for the cabinet is illustrated in FIG. 3. The method of construction in this embodiment involves cutting a base recess 302 into an upper surface 303 of the base panel 301. Edges 304 and the cut recess are protected by the application of a primer, before being glued. For applications such as that described with reference to FIG. 1, when the cabinet will be exposed to environmental conditions, adhesives manufactured for use in structural glazing are considered acceptable, given their inherent resistance to degradation under ultraviolet light. Adhesives of this type are provided by Sika Services AG of Switzerland and are identified by the commercial designation Sikasil (registered trade mark). Prior to the application of the adhesive, surfaces, such as the base recess 302, must be clean, dry and free from grease. Mechanical grinding is performed on the surfaces to be bonded using an eccentric grinder of grain value eighty.

Following the grinding operation, the surface is cleaned with a clean grease free and fluff free cloth or cleansing paper soaked in an appropriate cleaning solution, such as that made available be Sika Services AG under the commercial designation Sika cleaning 205. Wiping should be performed in one direction only and cleaning cloths should be regularly replaced. Thereafter, a ventilation period of ten minutes is required before any further action is taken.

After cleaning the surfaces, a primer is applied, such as that produced by Sika Services AG and made available under the commercial designation Sika Tack Panel Primer. This primer is applied uniformly over the machined surface with a brush or felt and requires a ventilation time of at least thirty minutes before the adhesive is applied.

Although not requiring adhesive as such, a similar priming operation is also applied to the edges 304 of the base panel 301.

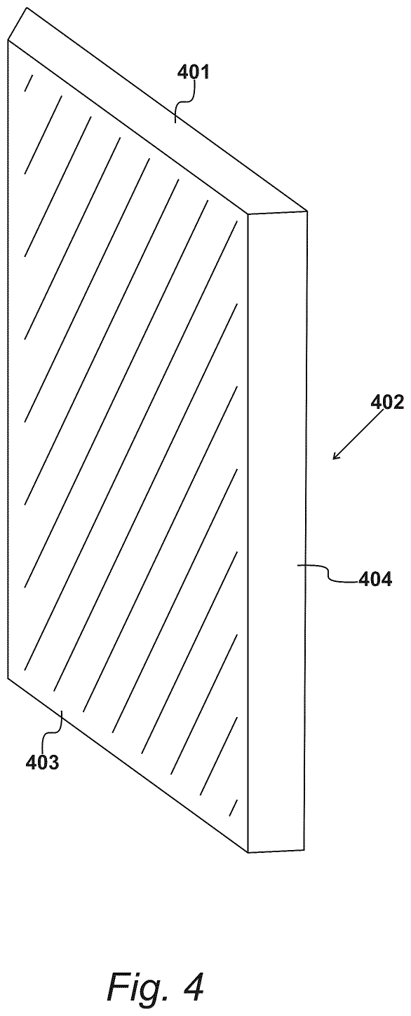

### FIG. 4

A first wall 401 for the cabinet is shown in FIG. 4, cut from the panel illustrated in FIG. 2. The wall 401 has a durable outer surface 402 and, in this embodiment, a similar durable inner surface 403. Connection devices are provided for connecting the walls at adjacent edges, such as edge 404. In an embodiment, integrity is maintained by connecting the walls at adjacent edges without penetrating the outer durable surfaces.

In the embodiment of FIG. 4, to achieve this, the edges, including a first edge 404, are bevelled. The walls are then connected at adjacent edges by abutting respective bevelled edges.

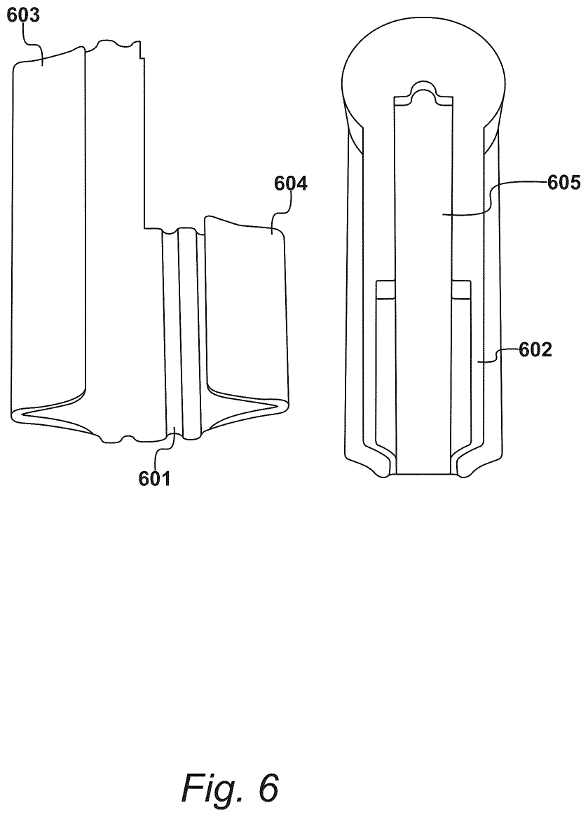

In this embodiment, a plurality of connection devices are deployed, as described with reference to FIG. 6.

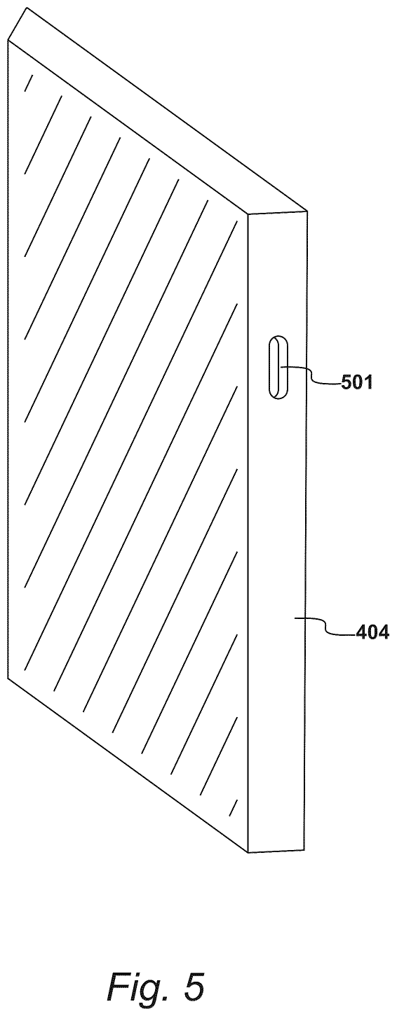

### FIG. 5

To allow for the deployment of the connection devices, an orifice 501 is cut into the bevelled edge 404. Similar orifices are cut into the other bevelled edges and additional orifices may be cut into each bevelled edge. In the example shown in FIG. 5, a single orifice 501 is shown for the purposes of illustration. However, additional orifices may be included in each bevelled edge, with an appropriate spacing therebetween, for different sizes of cabinet.

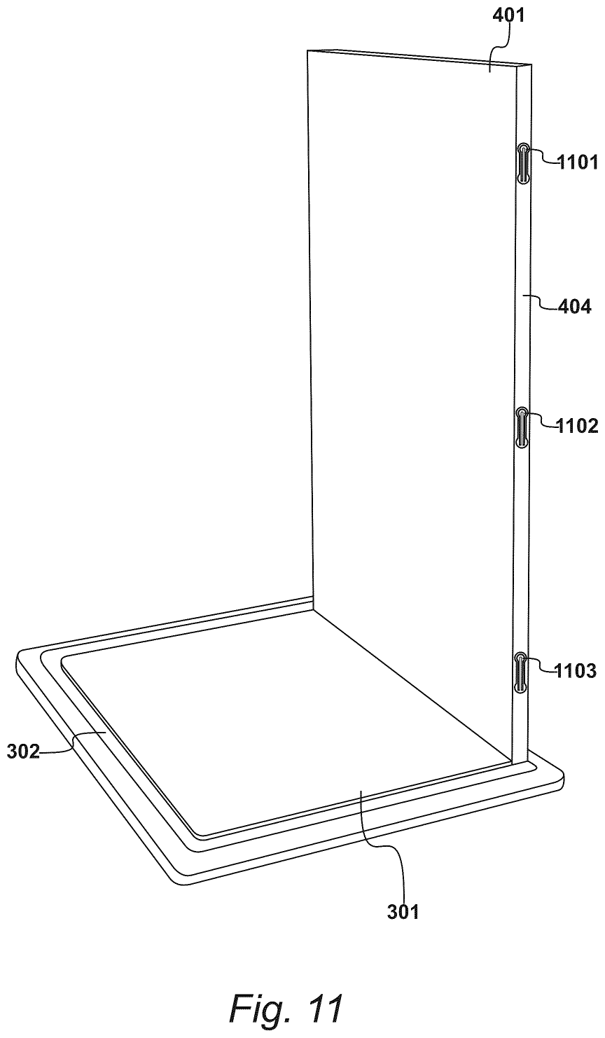

In the embodiment described with reference to FIG. 11, a total of three orifices have been cut in each bevelled edge, to accommodate three similar connection devices between the bevelled edges.

### FIG. 6

In an embodiment, each connection device includes a first connector portion 601 that engages with a second connector portion 602. The first connector portion 601 is located within a first bevelled edge and the second connector portion 602 is located within a second cooperating bevelled edge.

In an embodiment, both bevelled edges, via their respective orifices, receive components substantially similar to the second portion 602. The first portion 601 includes a locating section 603 and an extension section 604. Thus, the first connector portion 601 is first located in a channel (similar to channel 605) by means of its locating section 603, whereafter engagement is achieved by receiving the extension section 604 within the second portion 602.

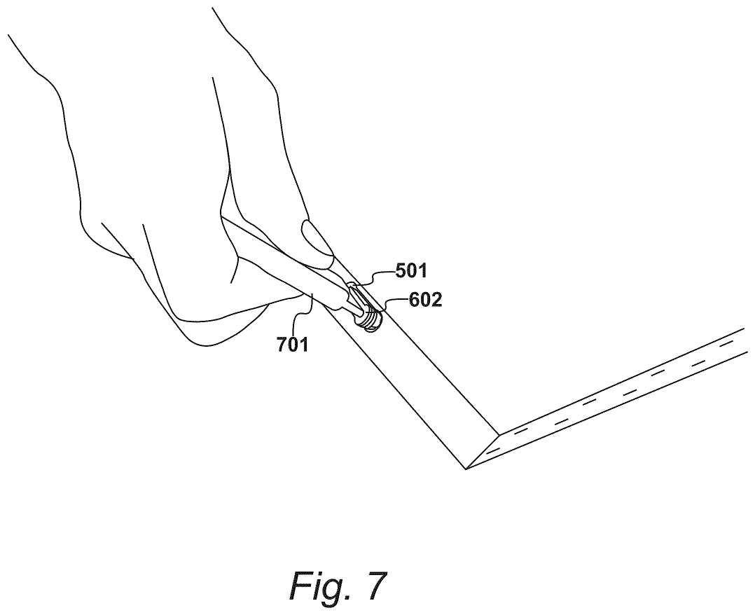

### FIG. 7

As illustrated in FIG. 7, a second portion 602 is located within an orifice 501 using an appropriate application tool 701.

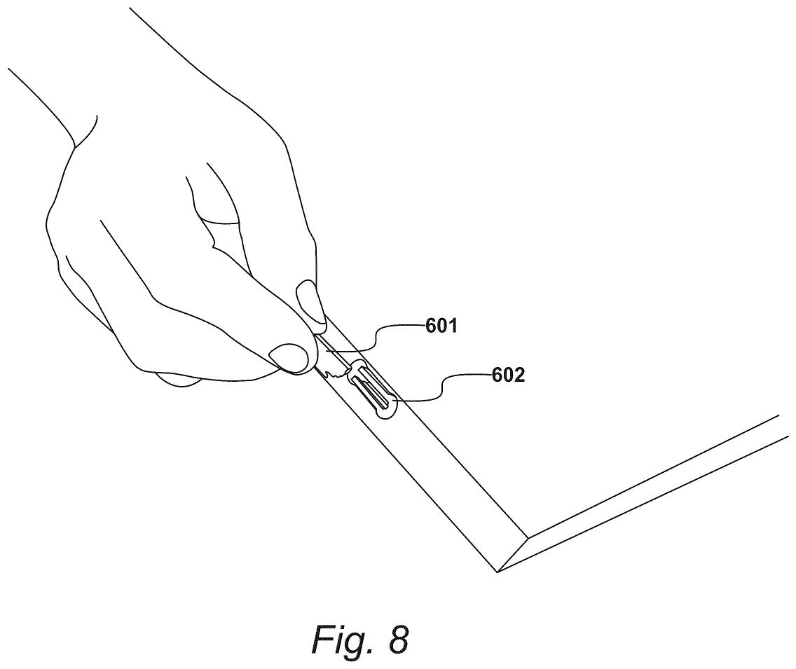

### FIG. 8

After using the application tool, as described with reference to FIG. 7, the first portion 601 is located (within a second portion 602) by means of the locating section 603. The resulting combination effectively defines a first portion subassembly and each subassembly of this type is individually assembled, as illustrated in FIG. 8.

Examples of connectors of this type are available from OVVO Technology (registered trade mark) of County Louth, Republic of Ireland.

Installation instructions from OVVO Technology suggests that the devices should be received within orifices 501, such that they lie flush with the surface of the edge 404. However, in this embodiment, the orifices 501 are milled to a lesser depth, such that, when the connector portions are received, they are slightly proud of the surface of the edge 404. Thus, as the edges are brought together, a gap is created between them for receiving an adhesive, of the type identified above.

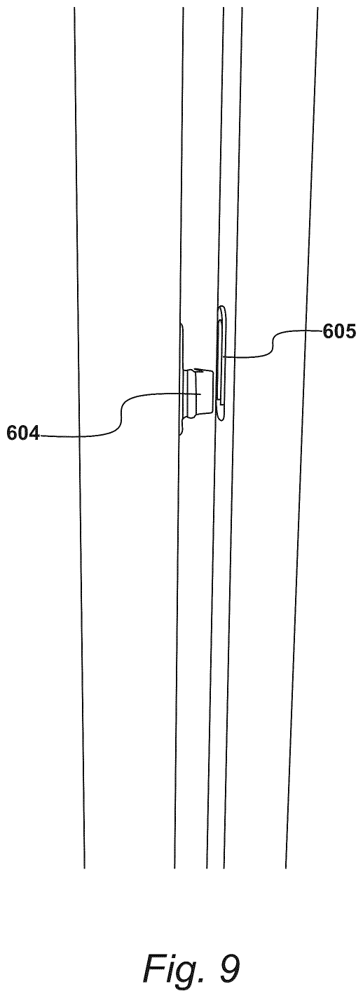

### FIG. 9

As illustrated in FIG. 9, walls are assembled, in this embodiment, by receiving extension sections 604 within respective channels 605. Before being connected as illustrated in FIG. 9, adhesive is applied to each of the surfaces.

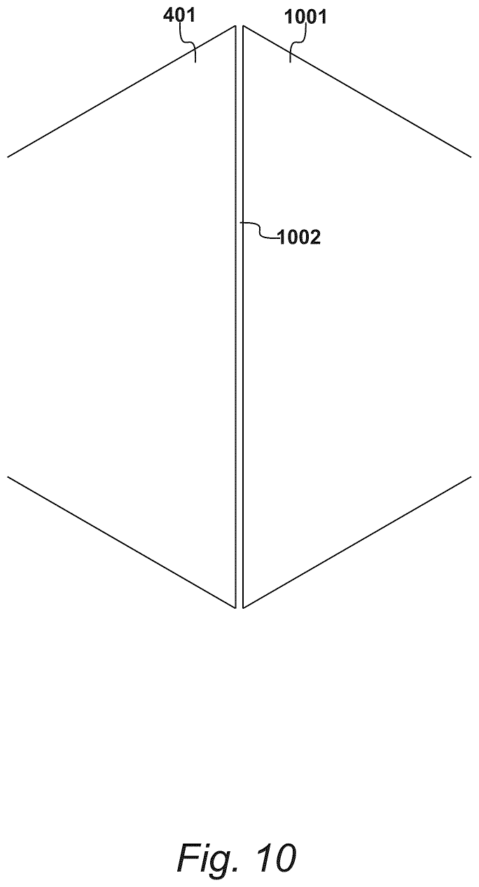

### FIG. 10

As illustrated in FIG. 10, the first wall 401 has been connected to a second wall 1001. The positioning of the connection devices results in a gap 1002 being established between the first wall 401 and the second wall 1001. The gap 1002 provides space for the adhesive previously applied to the bevelled edges, including edge 404.

Thus, the extension section 604 is located within the channel 605. The extension section is then secured by the channel by a displacement of the second wall 1001 relative to the first wall 401.

### FIG. 11

The embodiment previously described provides a method of constructing a cabinet for housing electrical equipment. As described with reference to FIG. 3, a base recess 302 is cut into an upper surface 303 of a base 301. The first wall 401 is located within a portion of the base recess.

In the arrangement shown in FIG. 11, bevelled edge 404 includes a first connection device 1101, a second connection device 1102 and a third connection device 1103.

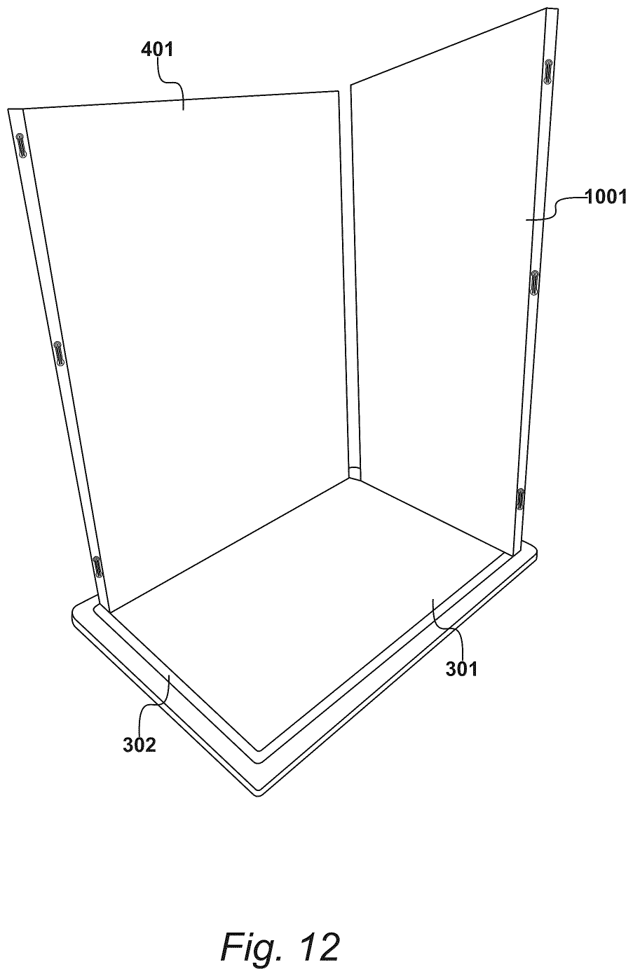

### FIG. 12

Following the method of this embodiment, the second wall 1001 is also located within a portion of the base recess 302. Thus, as previously described, the first wall and the second wall both include durable outer surfaces and side edges.

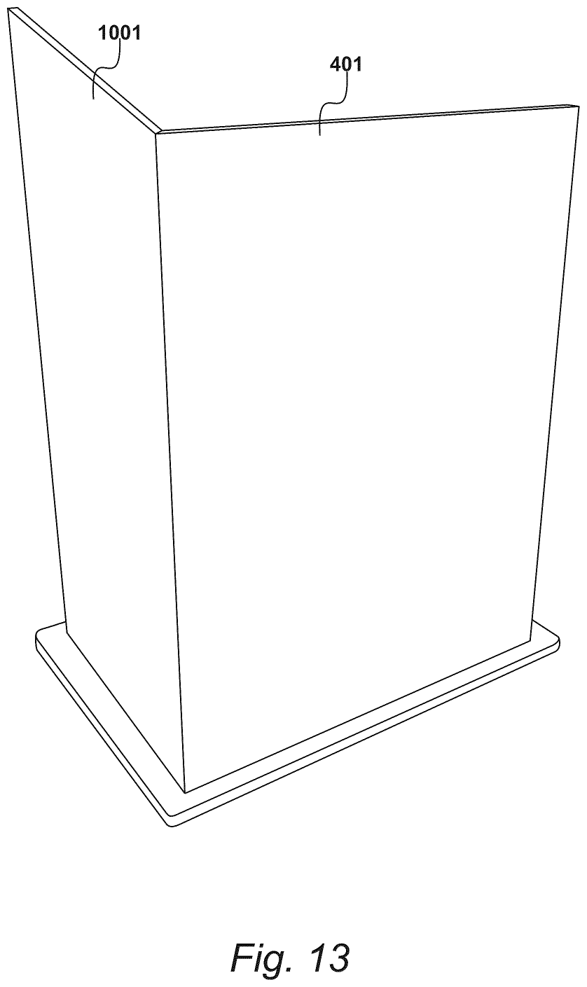

### FIG. 13

As illustrated in FIG. 13, the first edge 404 of the first wall 401 has been connected to a second edge of the second wall 1001. Furthermore, this connection has been achieved without penetrating the durable outer surface of the first wall and without penetrating the durable outer surface of the second wall.

### FIG. 14

The method of constructing the cabinet for electrical equipment, according to an embodiment, comprises the steps of cutting high pressure compact laminate to establish a plurality of walls, such as those described with reference to FIG. 13, and a roof, wherein the high-pressure compact laminate has a core and a durable outer surface, as described with reference to FIG. 2. The roof is arranged upon the walls to construct a cabinet of the type described with reference to FIG. 1. Thus, the roof has a lower portion 103, an upper portion 104 and support members.

As shown in FIG. 14, the upper portion 104 has been raised to reveal part of the lower portion 103. In this embodiment, a first support member 1401, a second support member 1402, a third support member 1403 and a fourth support member 1404 have been attached to the lower portion 103 such that they support the upper portion 104 upon the lower portion 103 while defining an air gap 105 between the lower portion 103 and the upper portion 104.

A plurality of vent holes 1405 have been cut in the lower portion 103 to facilitate the venting of warm air from inside the cabinet. The vent holes 1405 are covered with a mesh 1406 to prevent the ingress of solids and liquids, as described with reference to FIG. 15.

As described with reference to FIG. 1, in this embodiment, the roof is a couple roof defining a ridge, such that the upper portion comprises a first board 111 and a second board 112, as described with reference to FIG. 1. In the embodiment shown in FIG. 14, the lower portion 103 follows the shape of the upper portion and is implemented by means of a third board 1413 and a fourth board 1414. In FIG. 14, the fourth board 1414 is shown in its operational configuration but the third board 1413 is shown in an elevated configuration, making visible the underside of the venting holes 1405.

The third board and the fourth board may be identified as including a ridge section 1415 and a gutter section 1416. The ridge sections of both the third board and the fourth board include the vent holes 1405.

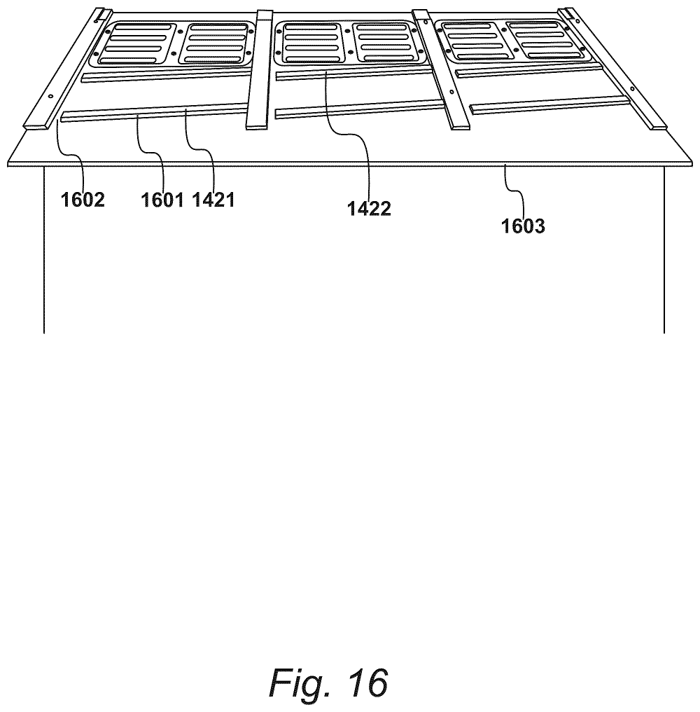

In the embodiment of FIG. 14, the gutter sections of the third board and the fourth board include first obstructors 1421 and second obstructors 1422 between the support members 1401 to 1404, described in detail with reference to FIG. 16. The lower surface of the first board 111 and the lower surface of the second board 112 include third obstructors 1423. The third obstructors are located between a pair of support members (1401, 1402; 1402, 1403; or 1403, 1404) and between respective first obstructors 1421 and respective second obstructors 1422. In an embodiment, these obstructors 1421 to 1423 may be implemented as brushes to prevent solid objects being inserted into the space 105 between the first portion and the second portion. However, in the embodiment of FIG. 14, the obstructors are solid baffles 1421 to 1423 that allow air to flow over while preventing the ingress of solid objects.

### FIG. 15

As illustrated in FIG. 15, a mesh 1501 is deployed over the vent holes 1405 on the upper surface of the lower portion of the roof. For each group of eight vent holes, a mesh cover 1502 secures a mesh 1501 in place. Furthermore, the mesh 1501 is blistered such that, at the position of each vent hole, the mesh 1503 extends above the surface of the mesh cover 1502, to improve airflow characteristics. In particular, the configuration enhances the transfer of warm air out of the cabinet.

In an embodiment, the mesh is a stainless steel mesh fabricated from grade 316 stainless steel. A mesh of this type designated SW30 has a hole size of 0.57 mm with a wire thickness of 0.28 mm such that a square metre of the mesh typically weighs 1.17 kg.

### FIG. 16

The first obstructors 1421 and the second obstructors 1422 are shown in FIG. 16. The obstructors 1421, 1422 are between the support members. The obstructors are not horizontal but slope to facilitate the removal of condensed water. Furthermore, at its lower end 1601, a gap 1602 is provided between the end 1601 of the obstructor 1421, 1422 and the first support member 1401. In this way, it is possible for condensed water to flow over a gutter edge 1603 of the roof.

The invention claimed is:

1. An apparatus establishing a cabinet for electrical equipment, comprising a plurality of walls and a roof, wherein:
said walls and said roof consist of high-pressure compact laminate having a core and a durable outer surface that comprises a polyurethane acrylate binder;
said roof comprises a lower portion, an upper portion and support members;
said support members support said upper portion upon said lower portion while defining an air gap between said lower portion and said upper portion;
said lower portion comprises a plurality of vent holes to facilitate venting of warm air from inside said cabinet; and
said vent holes are covered by a mesh to prevent ingress of solids and liquids.

2. The apparatus of claim 1, wherein said cores comprise wood-based fibres impregnated with a thermosetting resin.

3. The apparatus of claim 1, comprising connection devices, wherein:
said walls have bevelled side edges; and
adjacent bevelled edges are connected by said connection devices without penetrating said durable outer surfaces.

4. The apparatus of claim 1, wherein:
said roof is sloped; and
a pitch of said upper portion is substantially the same as a pitch of said lower portion.

5. The apparatus of claim 1, wherein:
said mesh is a stainless steel mesh;
said stainless steel mesh is applied over an upper surface of said vent holes; and
said stainless steel mesh is blistered upwards at a position of said vent holes.

6. The apparatus of claim 5, wherein:
said roof is a couple roof defining a ridge, such that said upper portion comprises a first board sloping in a first direction and a second board sloping in a second direction.

7. The apparatus of claim 6, wherein:
said lower portion comprises a third board and a fourth board;
said third board and said fourth board comprise a ridge section and a gutter section;
said ridge section of said third board comprises a first subset of said vent holes; and
said ridge section of said fourth board comprises a second subset of said vent holes.

8. The apparatus of claim 7, wherein:
said gutter section of said third board comprises first obstructors and second obstructors between said support members;
said gutter section of said fourth board comprises first obstructors and second obstructors between said support members;
a lower surface of said first board comprises third obstructors located between said support members and between said first obstructors and said second obstructors of said third board; and
a lower surface of said second board comprises third obstructors located between said support members and between said first obstructors and said second obstructors of said fourth board.

9. The apparatus of claim 8, wherein said first obstructors and said second obstructors of said third board, said first obstructors and said second obstructors of said fourth board, said third obstructors of said first board, and said third obstructors of said second board are solid baffles that allow said warm air to flow over while preventing said ingress of said solids.

10. The apparatus of claim 9, wherein said first obstructors and said second obstructors of said third board, said first obstructors and said second obstructors of said fourth board, said third obstructors of said first board, and said third obstructors of said second board slope to facilitate removal of condensed water.

11. A method of constructing a cabinet for electrical equipment, comprising steps of:
cutting high-pressure compact laminate to establish a plurality of walls and a roof, wherein said high-pressure compact laminate has a core and a durable outer surface that comprises a polyurethane acrylate binder;
arranging said roof upon said walls, wherein said roof has a lower portion, an upper portion and support members;
configuring said support members to support said upper portion upon said lower portion while defining an air gap between said lower portion and said upper portion;
cutting a plurality of vent holes in said lower portion to facilitate venting of warm air from inside said cabinet; and
covering said vent holes with a mesh to prevent ingress of solids and liquids.

12. The method of claim 11, wherein said cores of said high-pressure compact laminate are produced by impregnating wood-based fibres with a thermosetting resin.

13. The method of claim 11, comprising steps of:
bevelling side edges of said walls; and
connecting adjacent bevelled edges using connection devices that do not penetrate said durable outer surfaces of said high-pressure compact laminate.

14. The method of claim 11, wherein said arranging step comprises arranging a sloped roof, such that a pitch of said upper portion is substantially the same as a pitch of said lower portion.

15. The method of claim 11, wherein said covering step comprises covering said vent holes with a stainless steel mesh, and further comprising steps of:
applying said stainless steel mesh over an upper surface of said vent holes; and
blistering said stainless steel mesh upwards at a position of said vent holes.

16. The method of claim 15, wherein:
said roof is a couple roof defining a ridge, such that said upper portion comprises a first board sloping in a first direction and a second board sloping in a second direction.

17. The method of claim 16, comprising steps of:
constructing said lower portion from a third board and a fourth board;
identifying a ridge section and a gutter section in said third board and said fourth board;
creating a first subset of said vent holes in said ridge section of said third board; and
further creating a second subset of said vent holes in said ridge section of said fourth board.

18. The method of claim 17, comprising the steps of:
locating first obstructors and second obstructors upon said gutter section of said third board between said support members;
locating first obstructors and second obstructors upon said gutter section of said fourth board between said support members;
fixing third obstructors to a lower surface of said first board between said support members and between said first obstructors and said second obstructors of said third board; and
fixing third obstructors to a lower surface of said second board between support members and between said first obstructors and said second obstructors of said fourth board.

19. The method of claim 18, wherein said first obstructors and said second obstructors of said third board, said first obstructors and said second obstructors of said fourth board, said third obstructors of said first board, and said third obstructors of said second board are solid baffles that allow said warm air to flow over while preventing said ingress of said solids.

20. The method of claim 19, wherein said fixing steps comprise fixing said third obstructors of said first board and said third obstructors of said second board to slope, thereby to facilitating removal of condensed water.
